(19) United States
(12) Patent Application Publication
(10) Pub. No.: US 2025/0216801 A1
(43) Pub. Date: Jul. 3, 2025

(54) MIRROR DEVICE, PROJECTION OBJECTIVE AND METHOD FOR MEASURING THE TEMPERATURE OF A MIRROR

(71) Applicant: Carl Zeiss SMT GmbH, Oberkochen (DE)

(72) Inventors: Andreas Raba, Niederschoenenfeld (DE); Matthias Manger, Aalen (DE); Hans Michael Stiepan, Aalen (DE); Joern Weber, Aalen (DE)

(21) Appl. No.: 19/086,269

(22) Filed: Mar. 21, 2025

Related U.S. Application Data
(63) Continuation of application No. PCT/EP2023/075317, filed on Sep. 14, 2023.

(30) Foreign Application Priority Data
Sep. 28, 2022 (DE) 102022210245.2

(51) Int. Cl. G03F 7/00; G01J 5/00

(52) U.S. Cl. CPC G03F 7/70891; G03F 7/70316; G01J 5/0003

(57) ABSTRACT

A mirror device, for example for a microlithographic projection exposure system, comprises a mirror, a sensor unit and a control unit. The mirror comprises a mirror body and a reflective surface provided on the mirror body. The sensor unit is designed to detect infrared radiation given off by the mirror body in order to derive a temperature measurement value therefrom and to send the temperature measurement value to the control unit. The mirror comprises a target with an increased emissivity for infrared radiation. The disclosure also relates to a method for measuring the temperature of a mirror.

### CROSS-REFERENCE TO RELATED APPLICATIONS

The present application is a continuation of, and claims benefit under 35 USC 120 to, international application No. PCT/EP2023/075317, filed Sep. 14, 2023, which claims benefit under 35 USC 119 of German Application No. 10 2022 210 245.2, filed Sep. 28, 2022. The entire disclosure of each of these applications is incorporated by reference herein.

### FIELD

The disclosure relates to a mirror device, such as for a microlithographic projection exposure apparatus, to a projection lens, and to a method for measuring the temperature of a mirror.

### BACKGROUND

Microlithography projection exposure apparatuses are utilized for the production of integrated circuits with particularly small structures. A mask (=reticle) illuminated with very short-wave deep ultraviolet or extreme ultraviolet radiation (DUV or EUV radiation) is imaged onto a lithography object in order to transfer the mask structure to the lithography object.

The projection exposure apparatus comprises a plurality of mirrors at which the radiation is reflected. In general, the mirrors have a precisely defined shape and are precisely positioned in order that the imaging of the mask onto the lithography object is of sufficient quality.

During operation, the projection exposure apparatus is subjected to influences which have an influence on the imaging quality. By way of example, if a thermal expansion leads to a change in the geometric shape of a mirror, then the wavefront of the radiation reflected at the mirror changes. For proper operation of the projection exposure apparatus, it is helpful to have information concerning the temperature of the mirror. The temperature information can be used for example to control a heating unit or a cooling unit, such that the temperature of the mirror is kept at a constant value, or to suitably adjust the projection exposure apparatus after a temperature change.

DE 10 2012 201 410 A1 and DE 10 2020 205 752 A1 disclose detecting infrared radiation emitted by a mirror body in order to obtain information about the temperature of the mirror body. It has proved to be far from easy to obtain temperature information of sufficient accuracy in this way.

### SUMMARY

The disclosure presents a mirror device, a projection lens and a method for measuring the temperature of a mirror which can avoid certain disadvantages.

In an aspect, the disclosure provides a mirror device suitable, for example, for a microlithographic projection exposure apparatus. The mirror device comprises a mirror, a sensor unit and a control unit. The mirror comprises a mirror body and a reflective surface formed on the mirror body. The sensor unit is designed to detect infrared radiation given off by the mirror body in order to derive a temperature measurement value therefrom and to send the temperature measurement value to the control unit. The mirror body comprises a target with an increased emissivity for infrared radiation.

In the case of temperature measurements on the basis of infrared radiation, it is not always very easy to distinguish what proportion of the infrared radiation detected by a sensor unit was emitted by the mirror body and what proportion is background radiation. Background radiation may emanate from a frame structure of the mirror device or from an adjacent housing, for example. The disclosure proposes reducing this uncertainty by equipping the mirror with a target having an increased emissivity for infrared radiation. The increased emissivity results in an increase in the proportion of the relevant infrared radiation relative to the background radiation, as a result of which it is possible to improve the quality of the measurement.

The target has an increased emissivity compared with an adjacent region of the mirror. In relation to a scale extending between an ideal blackbody radiator with the emissivity ε(T)=1 and an ideal reflector with an emissivity ε(T)=0, the emissivity of the target can be higher than the emissivity of the adjacent region of the mirror by at least 20%, such as at least 40%, for example by at least 60%. If the adjacent region has an emissivity of ε(T)=0.5, an emissivity of the target of ε(T)=0.6 is increased by 20%. The indications concerning emissivity each relate to the wavelength range within the IR spectrum to which the sensor unit is sensitive.

The temperature measurement value recorded by the sensor unit can concern the temperature of the target. A temperature measurement value which is valid for the mirror body can be derived from the temperature of the target. If the mirror body has a temperature which is constant distributed over the body, then the temperature measurement value applies to the entire mirror body. If the temperature varies within the mirror body, then the temperature measurement value can apply to a local region within the mirror body. It is also possible to determine a temperature measurement value which corresponds to an average value over a plurality of local regions of the mirror body. The control unit can be designed to process the temperature measurement value recorded by the sensor unit, or a value derived therefrom.

During operation of the projection exposure apparatus, energy is constantly fed to the mirror because part of the incident EUV/DUV radiation is absorbed. In one embodiment, the disclosure is implemented without additional energy being introduced into the mirror device for the purpose of the temperature measurement. The measurement can thus be based solely on the energy which is fed to the mirror anyway during operation of the projection exposure apparatus. A thermographic measurement can be carried out. In order to deduce the temperature from the measured radiation power, a calibration can be effected with reference to an ideal blackbody radiator.

The sensor unit can comprise an infrared sensor in order to detect infrared radiation (IR radiation) emanating from the mirror body. The infrared sensor can be configured as an image sensor, such that the IR radiation emanating from the mirror body can be detected in a spatially resolved manner. Depending on sensitivity and wavelength range, for example, bolometers, thermopiles or semiconductor sensors (InSb, HgCdTe) can be used as detector elements.

The reflective surface of the mirror can have a high reflectivity for EUV radiation and/or DUV radiation. The reflective surface of the mirror can be formed by a highly reflective coating. This can involve an optical layer system in the form of a multilayer coating, in particular a multilayer coating having alternating layers of molybdenum and silicon. Using such a coating, it is possible to reflect approximately 70% of the incident EUV radiation. The approximately 30% that remains is absorbed and can lead to heating of the EUV mirrors. The term EUV radiation denotes electromagnetic radiation in the extreme ultraviolet spectral range with wavelengths of between 5 nm and 100 nm, for example with wavelengths of between 5 nm and 30 nm. DUV radiation is in the deep ultraviolet spectral range and has a wavelength of between 100 nm and 300 nm.

A high reflectivity for EUV/DUV radiation is thus regularly accompanied by low emissivity for IR radiation. For an ideal blackbody radiator, ε(T)=1 holds true for the emissivity and R=1−ε(T)=0 holds true for the reflectivity. Real nontransparent bodies have emissivities ε(T)<1 and accordingly a reflectivity R−ε(T)>0. The low emissivity is accompanied by a high reflectivity, which has the consequence that background radiation emanating from a frame structure of the mirror device or from an adjacent housing, for example, may be specularly reflected into the infrared sensor, which may corrupt the measurement result. If, in the context of the disclosure, the IR radiation emanating from a body is detected for the purpose of the temperature measurement, then the region adjacent to the target can have an emissivity ε for IR radiation of at least 0.15, for example at least 0.5. The indications concerning emissivity each relate to the wavelength range within the IR spectrum to which the sensor unit is sensitive.

In one embodiment, the sensor unit is arranged in front of the reflective surface, such that IR radiation emanating from the mirror body can propagate rectilinearly to the sensor unit, without the mirror body being in the way. In order to obtain a meaningful measurement result, the target can be a measurement field formed in the reflective surface. The measurement field can have a higher emissivity for IR radiation than the reflective surface.

The measurement field can be arranged in the middle of the reflective surface, such that the measurement field is surrounded all around by the reflective surface. The emission properties of the measurement field can be as close as possible to those of an ideal blackbody radiator. One possibility for producing the measurement field with the desired emissivity involves providing the reflective surface in the region of the measurement field with a coating. It is also possible to apply a film to the reflective surface in the region of the measurement field. In a further variant, the region of the measurement field is cut out from the highly reflective coating of the reflective surface, such that the surface of the mirror and thus the measurement field is formed by a material of the mirror body arranged underneath.

The mirror can comprise an active optical surface, which is impinged on by EUV radiation during operation of the mirror device. The active optical surface can correspond to the reflective surface or can be smaller than the reflective surface. The mirror can have a target arranged on the surface of the mirror, the target being arranged outside the active optical surface. In one embodiment, the active optical surface surrounds the target all around. In one embodiment, the target is arranged outside the active optical surface but within the reflective surface. The target can be surrounded all around by the reflective surface. The target can be configured as a measurement field arranged on the surface of the mirror.

In order to be able to reflect a sufficient amount of EUV/DUV radiation, the mirrors usually have a large reflective surface. By way of example, the reflective surface can have an area of at least 500 cm², such as at least 2000 cm², for example at least 10,000 cm². It is generally desirable for the targets making no relevant contribution to the reflection of the EUV/DUV radiation to be small in relation to the reflective surface. By way of example, a target can have an area which is less than 5 mm², such as less than 2 mm², for example less than 1 mm². For example, the size of the target can be between 1 μm² and 1 mm². The ratio between the size of the reflective surface and the size of the target can be at least 10⁴, such as at least 10⁶, for example at least 10⁸. The target can be configured as a measurement field.

The reflective surface can be provided with a plurality of targets, for example at least two, such as at least five, for example at least twenty, targets. The targets can be distributed uniformly over the reflective surface. For example, the largest circle within the reflective surface which is free of a target can have a surface area of not more than 20%, such as not more than 10%, for example not more than 5%, of the reflective surface.

The sensor unit can be directed at the targets, i.e. can be arranged such that the measurement signal representing the temperature of the mirror body is determined on the basis of the IR radiation emanating from the targets. Within the IR spectrum, it is desirable for the sensor unit to be sensitive to a wavelength range for which the target has a high emissivity. If the measurement field is formed by a silicon dioxide compound, as may be the case for example if the highly reflective coating is removed in the region of the measurement field, then the infrared sensor is desirably sensitive to long-wave IR radiation having wavelengths of between 7 μm and 14 μm.

Within the projection lens, a mirror device provided with targets within the active optical surface can have a near-pupil position. If a mirror is arranged near the pupil of the beam path, then the targets affect the entire field of the beam path to the same extent. By contrast, if the mirror is at a greater distance from the pupil, then a target may adversely affect a specific region within the field of the beam path, which is undesirable in many cases.

In order that other influences have little adverse effect on the temperature measurement, it cam be desirable for the conditions in the vicinity of the mirror to be kept as constant as reasonably possible. In this regard, a frame structure of the mirror device and/or a housing adjacent to the mirror device can be provided with a black surface, i.e. with a surface having a high emissivity for infrared radiation. The mirror device can comprise a cooling system in order to keep the frame structure and/or the housing at a constant temperature.

The mirror device can compromise a frame structure with the mirror body suspended therefrom. A movable suspension can be involved, such that the position of the mirror body is adjustable relative to the frame structure. The mirror device can comprise one or more actuators in order to change the position of the mirror body relative to the frame structure.

In addition or as an alternative to the targets on the surface of the mirror, the mirror device can comprise one or more targets arranged inside the mirror body. The emissivity of such a target is increased compared with the adjacent material of the mirror body. In one embodiment, the target is arranged in a cavity formed in the mirror body. The target can be formed for example by a coating applied to a material of the mirror body adjoining the cavity. The mirror body can have a channel extending from a surface of the mirror body as far as the target. The wall of the channel can be provided with a coating having a lower emissivity than the material of the mirror body and thus a high reflectance. In this way, the channel can form a kind of light guide for the infrared radiation given off by the target, such that the infrared radiation given off by the target is guided out of the mirror body toward the outside and can be detected there by a sensor unit.

In addition or as an alternative thereto, the mirror can comprise a target integrated into the material of the mirror body. The sensor unit can be sensitive to a wavelength range within the IR spectrum to which the material of the mirror body is transparent. This can help open up the possibility of detecting IR radiation emanating from the target integrated into the material of the mirror body. By way of example, the infrared sensor can be sensitive to medium-wave IR radiation and thus to a wavelength range to which silicon dioxide compounds are transparent.

Within the mirror body, a target can be formed which has an increased emissivity for IR radiation, i.e. the emissivity of which is higher than the emissivity of the surrounding mirror body material. The target can be for example a layer formed within the mirror body. The target layer can extend parallel to the reflective surface. If the mirror body comprises a main body, proceeding from which a layer construction comprising the optical layer system of the reflective surface is produced by way of additive manufacturing, then the target layer can be arranged between the optical layer system and the main body. If the layer construction comprises a surface protection layer, then the target layer can be arranged between the surface protection layer and the main body. If the mirror body includes a main body and a second partial body, the layer construction being implemented on the second partial body, then the target layer can also be arranged between the main body and the second partial body.

It is also possible for the target to be formed by a cavity which is formed within the mirror body and which is filled with a liquid having a high emissivity for IR radiation. The liquid can be water. In one embodiment, the cavity is a cooling channel and the liquid is water flowing through the cooling channel.

The infrared sensor can be arranged such that IR radiation emanating from the target can propagate through the material of the mirror body rectilinearly to the infrared sensor, without other obstacles being in the way. By way of example, the infrared sensor can be arranged adjacent to a rear side of the mirror body, the rear side being situated opposite the reflective surface. It is also possible for the mirror body to have a recess with the infrared sensor arranged therein. The path taken by the IR radiation through the material of the mirror body can be shortened in this way.

Energy can also be given off by the mirror body in the form of electrical charge if the reflective surface is subjected to EUV/DUV radiation during operation of the projection exposure apparatus. Within the optical layer system of the reflective surface, a standing wave can form upon excitation by the EUV/DUV radiation and can cause electrons to be released from the layer system. The electrons can form free charge carriers on the reflective surface, which can be conducted away via an electrical connection toward the outside to a ground. In an independently inventive variant, the number of dissipated charge carriers can be determined by measuring the current between the reflective surface and the ground.

The state of the standing wave changes depending on a heating-initiated change in the thickness of the layer system. This change can have the effect that the number of electrons released from the layer system also changes, such that the number of dissipated charge carriers can form a measure of the temperature of the mirror body in the region of the reflective surface. As the temperature changes, the period thickness of the optical layer system can change and the field strength at the surface of the optical layer system thus can change as well. The number of charge carriers is, in general, proportional to the field strength, such that to a first approximation there is a linear relationship between the temperature change and the measured photocurrent. Temperature changes can thus be ascertained from the measurement of the photocurrent.

The optical layer system can be electrically conductive and can be electrically insulated from the material of the mirror body. The reflective surface can be provided with a plurality of electrical contacts which are distributed over the circumference and via which the charge is dissipated.

In embodiments of the disclosure, the mirror device can also be fashioned such that the sensor unit comprises a light source used to guide a light signal to the mirror. Part of the energy introduced into the mirror body by the light signal is given off by the mirror body again and forms an amount of energy from which the temperature of the mirror body can be deduced.

The mirror body can be equipped with an interference layer system arranged between the reflective surface and the main body of the mirror body, the interference layer system acting as a thin-film interference filter. The layers differ in their refractive index, wherein the transition in refractive index between adjacent layers can take place continuously in the manner of a rugate filter or can take place discontinuously in the manner of a Bragg filter.

A light signal guided to the interference layer system can be reflected wavelength-selectively at the interference layer system. If the temperature of the mirror body changes, then the thickness of the interference layer system can change on account of thermal expansion, which has the consequence that the wavelength of the reflected portions of the light signal can change. This change in wavelength can be measured by a suitable light sensor. The temperature of the mirror body in the region of the interference layer system can be deduced from the measurement values.

The sensor unit having the light source and the light sensor can be arranged on the rear side or laterally with respect to the mirror body, such that the light signal can reach the interference layer system without impinging on the reflective surface beforehand. The angle of incidence can be between 0° and 60°. The light signal can have a wavelength to which the material of the mirror body is transparent. The wavelength can be in the visible range, for example. The interference layer system and the wavelength of the light signal can be coordinated with one another.

The temperature measurement can be carried out in a spatially resolved manner by separate evaluation of light signals from different regions of the interference layer system. For this purpose, for example, light from a plurality of light sources can be guided to the interference layer system and the reflected light signal can be evaluated via a sensor array. It is also possible for the surface of the interference layer system to be scanned by the sensor unit.

In one variant, the light source of the sensor unit is arranged in front of the reflective surface, such that the light signal is incident on the reflective surface. In this case, the optical layer system of the reflective surface itself can serve as a thin-film interference filter. It is generally desirable for the light signal used for measurement purposes to have the same wavelength as the EUV/DUV radiation reflected at the reflective surface during operation of the projection exposure apparatus. The light source can be configured as an EUV light source or as a DUV light source which emits radiation of the relevant wavelength. If the thickness of the layers within the optical layer system changes as a result of thermal expansion, then the reflected portion of the light signal can change, such that the temperature of the mirror body in the region of the reflective surface can be deduced from the measurement value.

In a further embodiment, the mirror body is provided with a thermochromatic layer. The thermochromatic layer can be arranged between the optical layer system and the main body of the mirror body. If the mirror body has a main body and a second partial body, then the thermochromatic layer can also be arranged between the main body and the second partial body.

The thermochromatic layer has the property of changing color in the event of a temperature change. The thermochromatic layer can comprise the inorganic compounds rutile or zinc oxide, for example, the molecular or crystal structure of which changes in the event of a temperature change, such that a change of color occurs. A light source can direct a light signal of suitable wavelength through the transparent material of the mirror body to the thermochromatic layer. From a change in the color of the reflected light portions, the light sensor can derive temperature information and send it to the control unit.

In one embodiment, the thermochromatic layer is fashioned such that a color change takes place upon a specific temperature threshold value being exceeded or undershot. If the temperature threshold value corresponds to the intended temperature of the mirror body during operation of the projection exposure apparatus, then the temperature signal recorded by the light sensor can be used directly to control temperature regulation of the mirror device. For example, a closed control loop can be provided, such that the mirror body is locally heated or cooled depending on the temperature signal of the light sensor.

The disclosure also relates to a projection lens of a projection exposure apparatus, wherein a mask is imaged onto a lithography object by way of a plurality of mirror devices, wherein at least one of the mirror devices is configured as a mirror device according to the disclosure. The projection lens can comprise at least two, such as at least three, for example at least five, mirror devices according to the disclosure. The temperature measurement value obtained by the sensor unit according to the disclosure can be used in a control system of the projection lens in order to control an operating parameter of the projection lens. For example, the operating parameter can be controlled in a closed control loop using the temperature measurement value. The disclosure furthermore relates to a projection exposure apparatus comprising such a projection lens.

The disclosure also relates to a method for measuring the temperature of a mirror of a microlithographic projection exposure apparatus. The mirror comprises a mirror body and a reflective surface formed on the mirror body. A sensor unit can detect an amount of energy given off by the mirror body in order to derive a temperature measurement value therefrom. The temperature measurement value can be sent to a control system of the microlithographic projection exposure apparatus. The mirror comprises a target with an increased emissivity for infrared radiation.

The disclosure encompasses developments of the method with features that are described in the context of the mirror device according to the disclosure. The disclosure encompasses developments of the mirror device with features that are described in the context of the method according to the disclosure.

### BRIEF DESCRIPTION OF THE DRAWINGS

The disclosure is described by way of example below on the basis of advantageous embodiments with reference to the accompanying drawings, in which:

FIG. 1: shows a schematic illustration of a projection exposure apparatus according to the disclosure;

FIG. 2: shows a schematic illustration of a mirror device according to the disclosure;

FIG. 3: shows a plan view of the mirror of the mirror device from FIG. 2;

FIG. 4: shows a sectional illustration of the mirror from FIG. 3 with a schematically illustrated sensor unit;

FIGS. 5-7: show the view according to FIG. 4 in the case of an alternative embodiment of the disclosure;

FIG. 8: shows a schematic illustration of a comparative example;

FIGS. 9-11: show schematic illustrations of comparative examples;

FIGS. 12 and 13: show the view according to FIG. 3 in the case of alternative embodiments of the disclosure;

FIG. 14: shows a further embodiment according to the disclosure.

### DETAILED DESCRIPTION

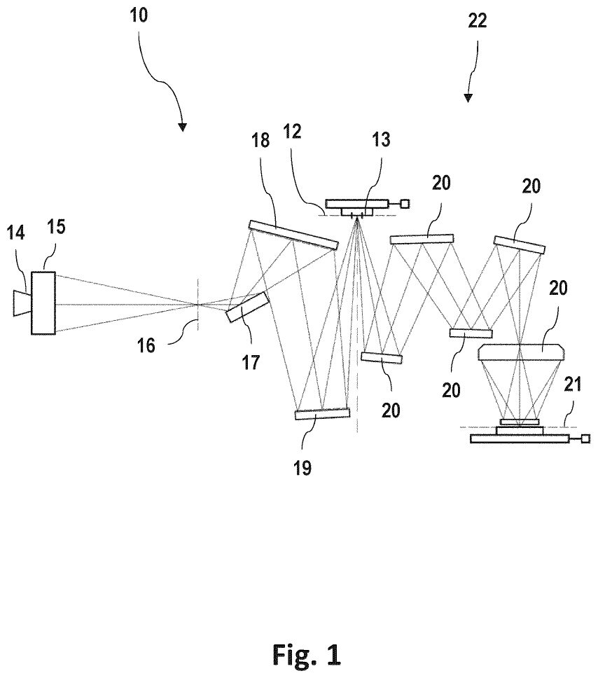

FIG. 1 schematically illustrates a microlithographic EUV projection exposure apparatus. The projection exposure apparatus comprises an illumination system 10 and a projection lens 22. An object field 13 in an object plane 12 is illuminated with the aid of the illumination system 10.

The illumination system 10 comprises an exposure radiation source 14, which emits electromagnetic radiation in the EUV range, i.e. with a wavelength of between 5 nm and 30 nm in particular. The illumination radiation emerging from the exposure radiation source 14 is first focused into an intermediate focal plane 16 by way of a collector 15.

The illumination system 10 comprises a deflection mirror 17, by which the illumination radiation emitted by the exposure radiation source 14 is deflected onto a first facet mirror 18. A second facet mirror 19 is disposed downstream of the first facet mirror 18. The individual facets of the first facet mirror 18 are imaged into the object field 13 by way of the second facet mirror 19.

With the aid of the projection lens 22, the object field 13 is imaged into an image plane 21 using a plurality of mirrors 20. Arranged in the object field 13 is a mask (also called reticle) which is imaged onto a light-sensitive layer of a wafer arranged in the image plane 9.

The various mirrors of the projection exposure apparatus at which the illumination radiation is reflected are configured as EUV mirrors. The EUV mirrors are provided with highly reflective coatings. This can involve multilayer coatings, in particular multilayer coatings having alternating layers of molybdenum and silicon. The EUV mirrors reflect approximately 70% of the incident EUV radiation. The approximately 30% that remains is absorbed and leads to heating of the EUV mirrors.

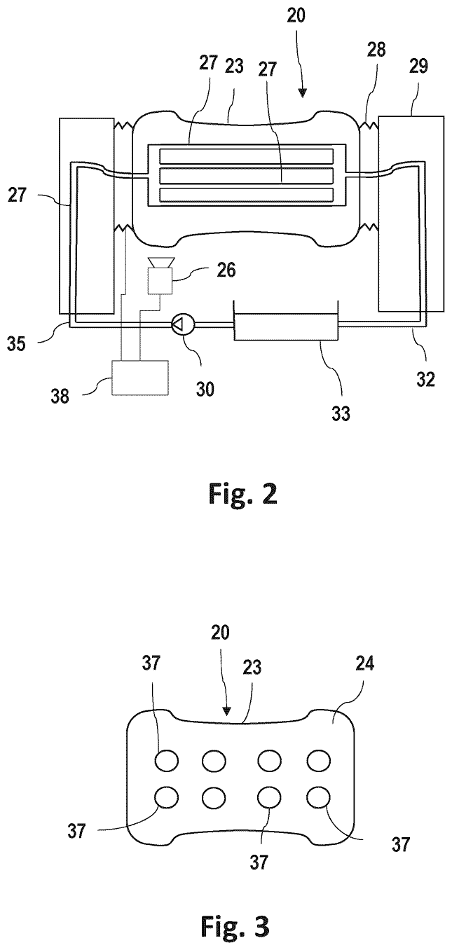

FIG. 2 shows a mirror device, in which a mirror body 23 of a mirror 20 is held on a frame structure 29 via actuators 28. The actuators 28 can be used to change the position of the mirror 20 relative to the frame structure 29 for the purpose of aligning and positioning the mirror 20 within the rigid body degrees of freedom. A reflective surface 24 at which incident EUV radiation is reflected is formed on the mirror body 23.

The mirror device is equipped with a cooling system comprising a coolant reservoir 33 filled with a cooling liquid and a pump 30. Using the pump 30, cooling liquid is drawn from the coolant reservoir 33 and guided via a first connecting line 35 to cooling channels 27. The cooling channels 27 extend over the frame structure 29 to the mirror body 23. A closed cooling circuit is formed via a return line 32. The cooling liquid absorbs heat resulting from the absorbed EUV radiation and dissipates this heat from the mirror body 23. At the transition between the frame structure 29 and the mirror body 23, the connecting lines 32, 35 are embodied as flexible hose lines in order not to impede the adjustment and alignment of the mirrors.

The cooling channels 27 are fashioned such that heat is dissipated both from the frame structure 29 and from the mirror body 23 and both are kept at a substantially constant temperature during operation of the projection exposure apparatus. Within the mirror body 23, the cooling channels 27 branch into a plurality of parallel channels, such that the heat is dissipated uniformly from the reflective surface 24. In the case of the projection exposure apparatus from FIG. 1, each of the mirrors 20 of the projection lens 22 is configured as a mirror device in accordance with FIG. 2.

The mirror device comprises a control unit 38, which performs various control tasks for the mirror device. Inter alia, the control unit 38 controls the actuators 28 in order to bring the mirror body 23 into a desired position and orientation relative to the frame structure 29, and controls the pump 30 of the cooling system in order to adjust the cooling capacity. One of the input variables processed by the control unit 38 when determining the control commands for the actuators 28 is temperature measurement values regarding the temperature of the mirror body 23, which the control unit 38 obtains from a sensor unit in the form of an IR camera 26 that is sensitive to IR radiation. The temperature measurement values are used as a basis for controlling operating parameters of the mirror device, such as for example the actuators 28 or the cooling capacity of the cooling system. The control can be effected within a closed control loop.

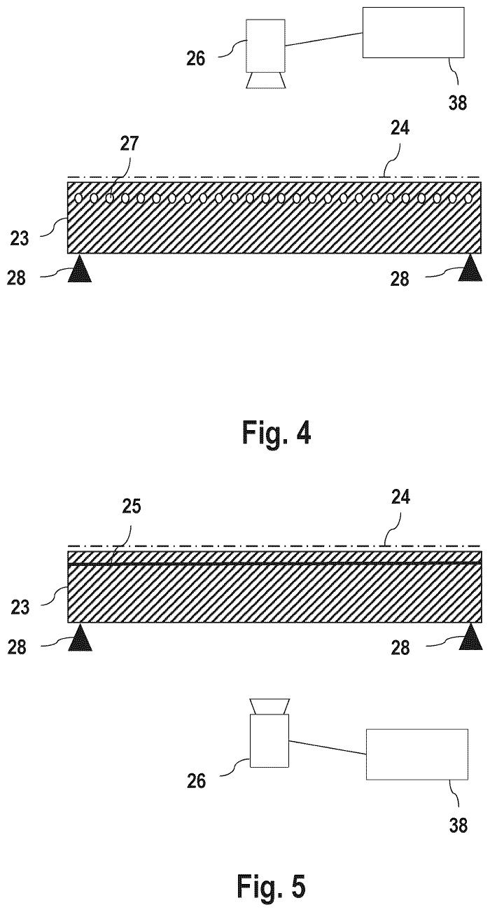

In accordance with FIG. 4, the IR camera 26 is directed at the reflective surface 24 of the mirror 20. The reflective surface is provided with a plurality of targets in the form of measurement fields 37, which are illustrated in an enlarged view in FIG. 3 for the sake of clarity. In actual fact, the measurement fields 37 each have an area of approximately 1 mm², while the horizontal extent of the reflective surface 24 is approximately 80 cm. The measurement fields 37 have a high emissivity for long-wave IR radiation, which in particular is significantly higher than the emissivity of the reflective surface 24. The measurement fields 37 are produced by the optical layer system 40 that forms the reflective surface 24 being removed in the region of the measurement fields 37, such that the silicon dioxide material of the mirror body 23 is freely accessible.

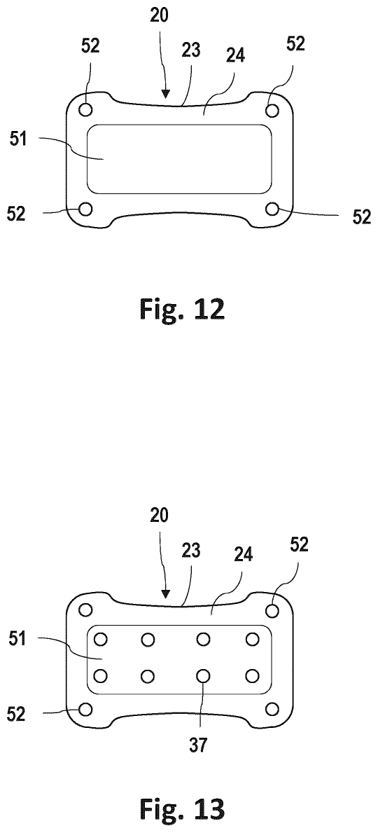

FIG. 12 illustrates an alternative embodiment, in which an active optical surface 51 is formed within the reflective surface 24, EUV radiation impinging on the active optical surface during operation of the projection exposure apparatus. The regions of the reflective surface 24 that are arranged outside the active optical surface 51 do not lie within the EUV beam path of the projection exposure apparatus. The targets 52 configured as measurement fields are arranged within the reflective surface 24, but outside the active optical surface 51. This has the advantage of preventing the EUV beam path from being adversely affected by the targets 52.

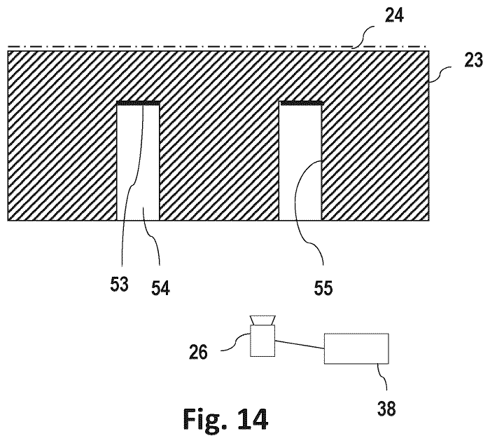

In the case of the further alternative embodiment in FIG. 13, the reflective surface 34 comprises both targets 37 arranged within the active optical surface 51 and targets 52 arranged outside the active optical surface 51. If the reflective surface 24 is densely occupied by targets 37, 52, it is easier to obtain spatially resolved temperature information from the surface of the mirror 20.

The IR camera 26, which is sensitive to long-wave IR radiation having a wavelength of the order of magnitude of 10 μm, records the IR radiation emitted by the entire reflective surface 24. However, only those measurement values which relate to the measurement fields 37, 52 are included in the further evaluation. On the basis of a previously performed calibration that related the measured radiation power to specific temperature measurement values, a temperature measurement value for each of the measurement fields 37, 52 is derived from the measurement values. The temperature measurement values are sent to the control unit 38 and evaluated there for the purpose of controlling the mirror device.

The meaningfulness of the temperature measurement values depends on the radiation power recorded by the IR camera 26 not being corrupted by interfering background signals. The background radiation cannot be completely avoided, since every body at a specific temperature emits a specific amount of IR radiation. The disclosure pursues the approach of keeping the background radiation constant. For this purpose, the components in the vicinity of the mirror 20 are kept at a constant temperature. FIG. 2 shows this on the basis of the example of the frame structure 29 cooled via the cooling channels 27. The components in the vicinity of the mirror 20 that are not illustrated in FIG. 2, such as for example housings and the like, are also cooled in a comparable manner. Furthermore, the surface of the components is fashioned such that it is black for long-wave IR radiation.

Within the projection lens 22, the mirror device can have a near-pupil position. If a mirror 20 is arranged near the pupil of the beam path, then the measurement fields 37, 52 affect the entire field of the beam path to the same extent. By contrast, if a mirror 20 is at a greater distance from the pupil, then a measurement field 37, 52 may adversely affect a specific region within the field of the beam path, which is undesirable in many cases.

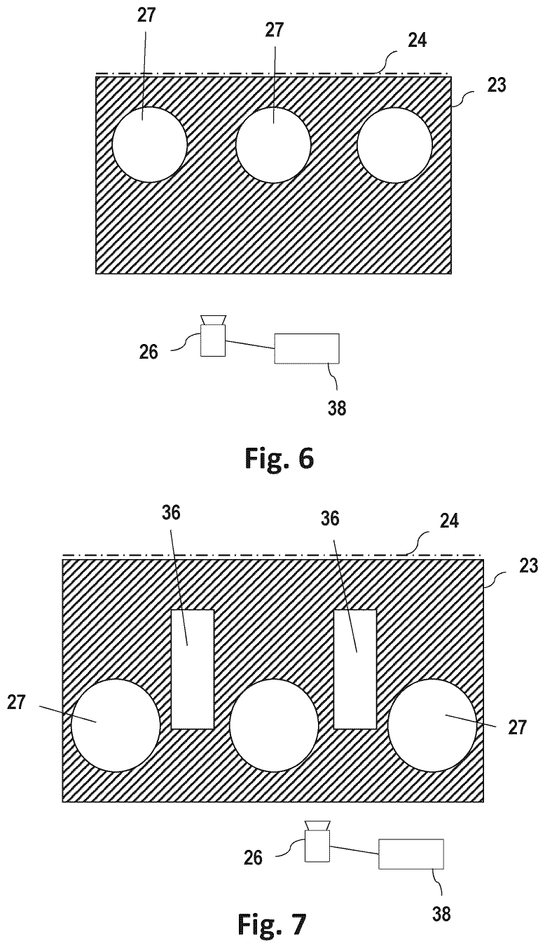

In the case of the alternative embodiment in accordance with FIG. 5, the IR camera 26 is arranged on the rear side of the mirror body 23. The IR camera is sensitive to medium-wave IR radiation having a wavelength of the order of magnitude of 4 μm, to which the material of the mirror body 23 is transparent. Near the reflective surface 24, the mirror body 23 is provided with a target layer 25 having a high emissivity for IR radiation of this wavelength. The IR radiation emitted by the target layer 25, this radiation being representative of the temperature of the mirror body 23 in the vicinity of the target layer 25, propagates through the material of the mirror body 23 to the IR camera 26. By evaluating the IR radiation emitted by the target layer 25, the IR camera 26 can determine temperature measurement values in a locally resolved manner and communicate them to the control unit 38.

FIG. 6 shows an embodiment in which the IR camera 26 is likewise directed at the rear side of the mirror body 23 and is sensitive to medium-wave IR radiation. The cooling water in the cooling channels 27 is black for IR radiation of this wavelength, such that the IR radiation emitted by the cooling water is representative of the temperature of the cooling water. The temperature of the mirror body 23 in the vicinity of the cooling channels 27 can be deduced from the temperature of the cooling water. The IR radiation emitted by the cooling water propagates through the transparent material of the mirror body 23 to the IR camera 26, which determines from the recorded radiation temperature measurement values which are locally resolved along the length of the cooling channels 27.

In the case of the embodiment in accordance with FIG. 7, cavities 36 are formed in the mirror body 23 in the region between the cooling channels 27 and the reflective surface 24. The cavities 36 are filled with water. In a manner comparable to that in the case of the exemplary embodiment in accordance with FIG. 6, the temperature of the water in the cavities 36 is determined by the IR camera 26 arranged on the rear side of the mirror body 23. Since the cavities 36 are situated nearer the reflective surface 24, temperature information is obtained from precisely that region of the mirror body 23 which is particularly relevant to the control of the mirror device.

FIG. 14 shows an alternative embodiment, in which the target 53 is arranged in a cavity 54 of the mirror body 23. The cavity 54 extends from the target 53 as far as the rear side of the mirror body 23 situated opposite the reflective surface 24. The end face of the cavity 54 is covered by the target 53. The lateral surface of the cavity 54 is provided with a coating having a high reflectivity for infrared radiation. Infrared radiation emitted by the target 53 is guided along the cavity 54 toward the outside as in a light guide. The infrared radiation is recorded by an IR camera 26. Temperature measurement values representing the temperature of the targets 53 in the cavities 54 are determined.

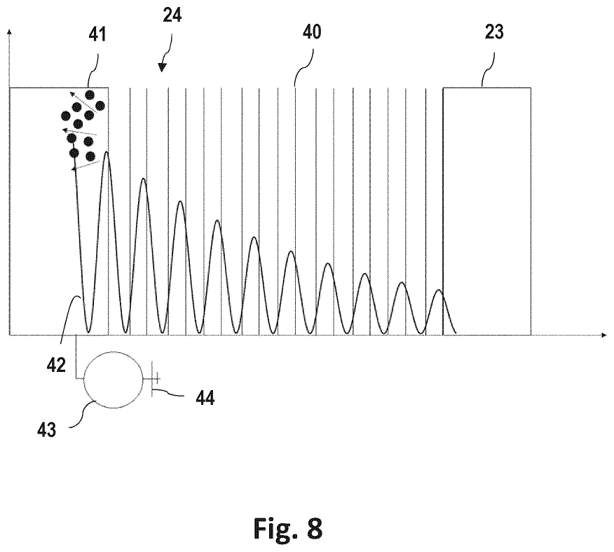

FIG. 8 schematically shows the construction of a mirror 20 comprising the mirror body 23 and, applied thereto, an optical layer system 40 comprising alternating layers of molybdenum and silicon. The optical layer system 40 forms the reflective surface 24. Using such a layer system, it is possible to reflect approximately 70% of the incident EUV radiation.

In the schematic illustration in FIG. 8, the Z-direction extending into the depth of the mirror body 23 proceeding from the reflective surface 24 is plotted on the horizontal axis. The vertical axis shows the energy of the incident EUV radiation 42 as amplitude of a sinusoidal curve. The EUV radiation 42 forms a standing wave in the optical layer system 40, wherein the amplitude decreases with increasing penetration into the optical layer system 40. An interaction between the EUV radiation 42 and the optical layer system 40 causes electrons to be released from their bonding within the optical layer system 40. The released electrons form free charge carriers 41 on the surface of the optical layer system 40. The optical layer system 40 is insulated from the mirror body 23, such that the charge carriers cannot flow away into the mirror body 23.

An electrical contact with a ground 44 is established in order to conduct away the charge carriers. A measuring instrument 43 is arranged between the ground 44 and the optical layer system 40, and measures the electric current and thus the number of charge carriers 41.

The interaction between the EUV radiation 42 and the optical layer system 40 is dependent on the thickness of the layers within the optical layer system 40. The thickness of the layers within the optical layer system 40 changes with temperature on account of thermal expansion. The strength of the electric field at the surface of the optical layer system 40 correlates with the thermal expansion of the optical layer system 40. The number of charge carriers 41, which is proportional to the strength of the electric field, thus forms a measure of the temperature. After suitable calibration, the measuring instrument 43 can derive temperature information from the number of charge carriers 41 and can send this information to the control unit 38.

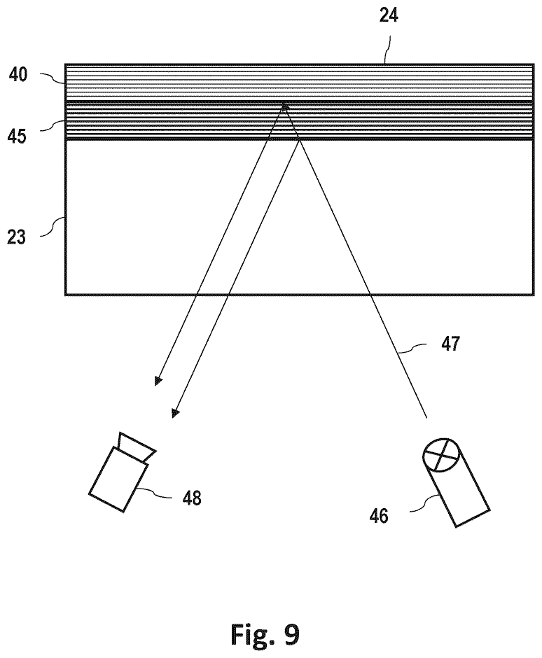

FIG. 9 shows an embodiment in which an interference layer system 45 is formed between the mirror body 23 and the optical layer system 40 of the reflective surface 24. The sensor unit comprises a light source 46 and a light sensor 48. The light source 46 emits a light signal 47 having a wavelength in the visible range. The light signal 47 is incident on the rear side of the mirror body 23 at an angle of incidence of between 0° and 60° and passes through the transparent material of the mirror body 23 to the interference layer system 45. The interference layer system 45 is subject to thermal expansion, such that the layer thickness of the layers within the interference layer system 45 forms a measure of the temperature of the mirror body 23 in the region of the reflective surface 24.

The interference layer system 45 can act as a Bragg filter with vertically alternating thicknesses or as a rugate filter with a continuously varied refractive index. In the event of a change in temperature in relation to a reference state, there is a change in the thickness and refractive index of the materials within the interference layer system 45. As a consequence, the resulting transmission or reflection spectrum of the filter shifts by Δλ. In the exemplary embodiment in accordance with FIG. 9, the light sensor 48 evaluates the reflection spectrum. Alternatively, the method can also be carried out with evaluation of the transmission spectrum. After suitable calibration, temperature information is derived from the reflection spectrum and is sent to the control unit 38.

The method can be carried out with a plurality of wavelengths. The accuracy can be increased by selecting wavelength ranges within which large reflection changes take place. By multiple application at different locations, e.g. via a laser diode array or a scanning laser, this method also enables locally resolved temperature measurement values to be obtained.

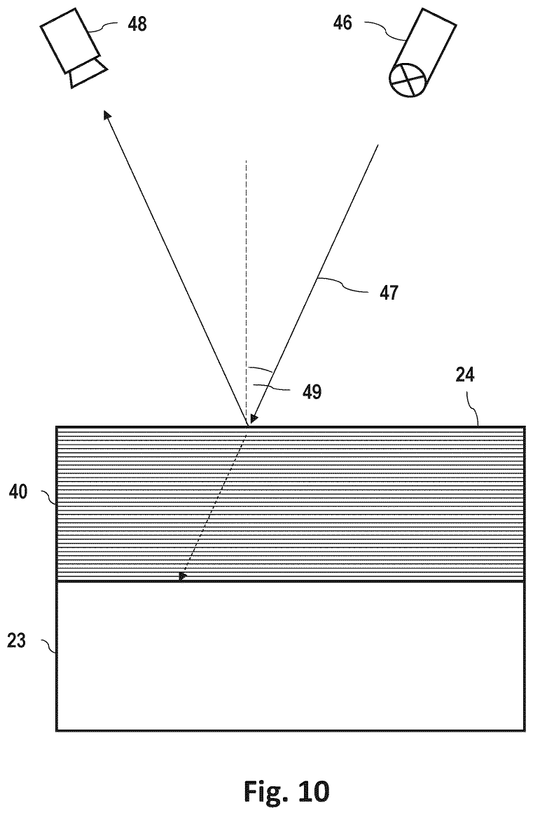

In the case of the variant in accordance with FIG. 10, the optical layer system 40 is used as an interference filter. The wavelength of the radiation emitted by the light source 46 is within the functional wavelength range of the optical layer system 40. In the present exemplary embodiment, the light source 46 emits EUV radiation having a wavelength of between 13 nm and 14 nm, which is incident on the surface of the optical layer system 40 at an angle 49 of incidence of between 0° and 45°. In a manner comparable to that in FIG. 9, the light sensor 48 determines temperature information from the reflection spectrum and sends this information to the control unit 38.

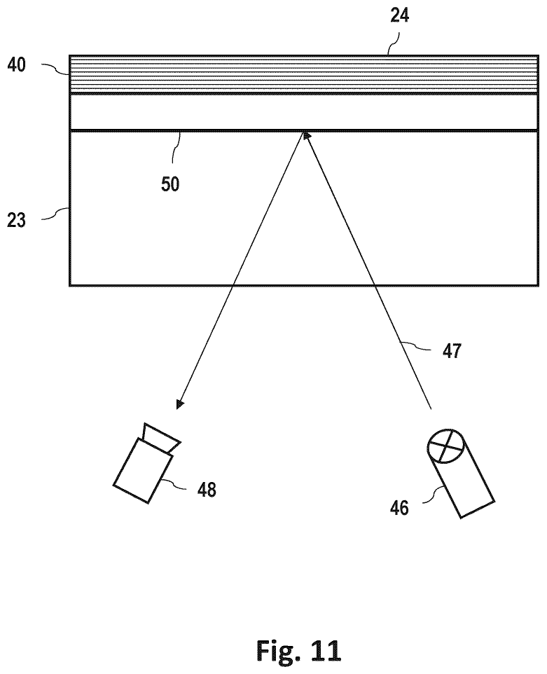

In the case of the exemplary embodiment in FIG. 11, the mirror body 23 is provided with a thermochromatic layer 50 arranged adjacent to the optical layer system 40. The thermochromatic layer 50 has the property of changing color in the event of a temperature change. The thermochromatic layer 50 can comprise the inorganic compounds rutile or zinc oxide, for example, the molecular or crystal structure of which changes in the event of a temperature change, such that a change of color occurs. The light source 46 can direct a light signal 47 of suitable wavelength through the transparent material of the mirror body 23 to the thermochromatic layer 50. From a change in the color of the reflected light portions, the light sensor 48 derives temperature information and sends it to the control unit 38. Using this method, too, it is possible to obtain spatially resolved temperature measurement values as described above.

In one embodiment, the thermochromatic layer 50 is fashioned such that a color change takes place upon a specific temperature threshold value being exceeded or undershot. If the temperature threshold value corresponds to the intended temperature of the mirror body 23 during operation of the projection exposure apparatus, then the temperature signal recorded by the light sensor 48 can be used directly to control temperature regulation of the mirror device. In particular, a closed control loop can be provided, such that the mirror body 23 is locally heated or cooled depending on the temperature signal of the light sensor 48.

What is claimed is:

1. A mirror device, comprising:
a mirror, comprising:
a mirror body;
a reflective surface supported by the mirror body; and
a target in the reflective surface; and
a sensor unit configured to detect infrared radiation emanating from the mirror body to derive a temperature measurement value therefrom,
wherein an emissivity for infrared radiation of the target is greater than an emissivity for infrared radiation of the reflective surface.

2. The mirror device of claim 1, further comprising a control unit control unit, wherein the sensor unit is configured to send the temperature measurement value to the control unit.

3. The mirror device of claim 1, wherein the sensor unit is configured to detect the infrared radiation emanating from the mirror body in a spatially resolved manner.

4. The mirror device of claim 1, wherein the sensor unit is in front of the reflective surface.

5. The mirror device of claim 1, wherein the reflective surface comprises an optical layer system, and the target is cut out from the optical layer system.

6. The mirror device of claim 1, wherein a ratio of a size of the reflective surface to a size of the target at least 10⁴:1.

7. The mirror device of claim 1, further comprising a further target outside an active optical surface of the mirror.

8. The mirror device of claim 1, wherein the sensor unit is configured to detect radiation having wavelengths of between 7 μm and 14 μm.

9. The mirror device of claim 1, further comprising a cooling system configured to keep a component at a constant temperature, wherein the component comprises a frame structure of the mirror device and/or a housing adjacent to the mirror device.

10. The mirror device of claim 1, wherein a frame structure of the mirror device comprises a surface having a high emissivity for infrared radiation, and/or wherein a housing adjacent to the mirror device comprises a surface having a high emissivity for infrared radiation.

11. The mirror device of claim 1, wherein an area of the reflective surface is at least 500 cm².

12. The mirror device of claim 11, wherein an area of the target is less than 5 mm².

13. The mirror device of claim 12, wherein a surface area of a largest circle within the reflective surface which is free of the target is at most 20% of a surface area of the reflective surface.

14. The mirror device of claim 1, wherein an area of the target is less than 5 mm².

15. The mirror device of claim 1, wherein a surface area of a largest circle within the reflective surface which is free of the target is at most 20% of a surface area of the reflective surface.

16. The mirror device of claim 1, comprising a plurality of targets in the reflective surface, wherein, for each target, an emissivity for infrared radiation of the target is greater than the emissivity for infrared radiation of the reflective surface.

17. The mirror device of claim 1, wherein the sensor unit is configured to detect infrared radiation emanating from the target.

18. A projection lens, comprising:
a plurality of mirror devices,
wherein at least one of the mirror devices comprises a mirror device according to claim 1, and the plurality of mirror devices is configured to image an object plane into an image plane.

19. A microlithographic projection exposure apparatus, comprising:
an illumination system; and
a projection lens comprising a plurality of mirror devices,
wherein the illumination system is configured to at least partially illuminate an object in an object plane of the projection lens, the plurality of mirror devices is configured to image the illuminated portion of the object into an image plane of the projection lens, and at least one of the plurality of mirror devices comprises a mirror device according to claim 1.

20. A method of measuring a temperature of a mirror of a microlithographic projection exposure apparatus, the mirror comprising a mirror body, a reflective surface supported by the mirror body, and a target in the reflective surface, the method comprising:
using a sensor unit to detect infrared radiation emanating from the mirror body to derive a temperature measurement value therefrom; and
sending the temperature measurement value to a control system of the microlithographic projection exposure apparatus,
wherein an emissivity for infrared radiation of the target is greater than an emissivity for infrared radiation of the reflective surface.
